(19) United States
(12) Patent Application Publication
(10) Pub. No.: US 2026/0019061 A1
(43) Pub. Date: Jan. 15, 2026

(54) SURFACE ACOUSTIC WAVE DEVICE WITH VARYING PIEZOELECTRIC LAYER THICKNESS

(71) Applicant: Skyworks Solutions, Inc., Irvine, CA (US)

(72) Inventor: Rei Goto, Osaka-Shi (JP)

(21) Appl. No.: 19/250,597

(22) Filed: Jun. 26, 2025

Related U.S. Application Data
(60) Provisional application No. 63/670,261, filed on Jul. 12, 2024.
(60) Provisional application No. 63/670,264, filed on Jul. 12, 2024.

(51) Int. Cl. H03H 9/02; H03H 3/08; H03H 9/145; H03H 9/17

(52) U.S. Cl. CPC H03H 9/02992; H03H 3/08; H03H 9/14544; H03H 9/17

(57) ABSTRACT

A surface acoustic wave device and a method of forming the surface acoustic wave device are disclosed. The surface acoustic wave device can include a piezoelectric layer with a bus bar region having a first thickness and a finger region having a second thickness less than the first thickness. The surface acoustic wave device can include an interdigital transducer electrode in electrical communication with the piezoelectric layer. The interdigital transducer electrode includes a bus bar and fingers that extend from the bus bar. The bus bar is positioned in the bus bar region and the fingers are positioned in the finger region.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/670,261, filed Jul. 12, 2024, titled “SURFACE ACOUSTIC WAVE DEVICE WITH INTERDIGITAL TRANSDUCER ELECTRODE PARTIALLY POSITIONED IN PIEZOELECTRIC LAYER,” and U.S. Provisional Patent Application No. 63/670,264, filed Jul. 12, 2024, titled “SURFACE ACOUSTIC WAVE DEVICE WITH PARTIALLY BURIED INTERDIGITAL TRANSDUCER ELECTRODE LAYER,” are hereby incorporated by reference under 37 CFR 1.57 in their entirety.

### BACKGROUND

### Field

Embodiments of this disclosure relate to surface acoustic wave devices.

### Description of Related Technology

Acoustic wave filters can be implemented in radio frequency electronic systems. For instance, filters in a radio frequency front end of a mobile phone can include acoustic wave filters. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. A surface acoustic wave resonator can include an interdigital transductor electrode on a piezoelectric substrate. The surface acoustic wave resonator can generate a surface acoustic wave on a surface of the piezoelectric layer on which the interdigital transductor electrode is disposed.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to a surface acoustic wave device including: a piezoelectric layer having a first surface and a second surface opposite the first surface; and an interdigital transducer electrode in electrical communication with the piezoelectric layer, the interdigital transducer electrode including a bus bar and fingers extending from the bus bar, the fingers being at least partially positioned below the first surface and at least partially positioned over the first surface, and the bus bar being positioned over the first surface.

In some embodiments, the techniques described herein relate to a surface acoustic wave device wherein the piezoelectric layer includes a bus bar region and a finger region, the finger region includes an active region and a gap region between the active region and the bus bar region, the fingers are at least partially positioned below the first surface in the active region.

In some embodiments, the techniques described herein relate to a surface acoustic wave device wherein the fingers are positioned over the first surface in the gap region.

In some embodiments, the techniques described herein relate to a surface acoustic wave device wherein the active region includes a center region and a border region between the center region and the gap region, the border region includes a piston mode structure.

In some embodiments, the techniques described herein relate to a surface acoustic wave device wherein the piston mode structure includes a trench formed in the piezoelectric layer.

In some embodiments, the techniques described herein relate to a surface acoustic wave device wherein the interdigital transducer electrode further includes a mini-bus bar in the gap region.

In some embodiments, the techniques described herein relate to a surface acoustic wave device wherein the fingers are at least partially positioned 50 nanometers or greater below the first surface in the active region.

In some embodiments, the techniques described herein relate to a surface acoustic wave device further including a support substrate.

In some embodiments, the techniques described herein relate to a surface acoustic wave device further including an intermediate layer positioned between the support substrate and the piezoelectric layer.

In some aspects, the techniques described herein relate to a surface acoustic wave device including: a piezoelectric layer having a first surface and a second surface opposite the first surface, the piezoelectric layer including a patterned recess recessed from the first surface; and an interdigital transducer electrode in electrical communication with the piezoelectric layer, the interdigital transducer electrode including a bus bar and fingers extending from the bus bar, at least a portion of the fingers disposed in the patterned recess, and the bus bar positioned over the first surface.

In some embodiments, the techniques described herein relate to a surface acoustic wave device wherein the piezoelectric layer includes a bus bar region and a finger region, the finger region includes an active region and a gap region between the active region and the bus bar region, the patterned recess is formed at least in the active region of the surface acoustic wave device.

In some embodiments, the techniques described herein relate to a surface acoustic wave device wherein the patterned recess is also formed in the gap region.

In some embodiments, the techniques described herein relate to a surface acoustic wave device wherein the patterned recess has a depth in a range between 50 nanometers and 500 nanometers.

In some embodiments, the techniques described herein relate to a surface acoustic wave device wherein interdigital transducer electrode includes a first layer and a second layer over the first layer.

In some embodiments, the techniques described herein relate to a surface acoustic wave device further including a support substrate and an intermediate layer positioned between the support substrate and the piezoelectric layer.

In some aspects, the techniques described herein relate to a method of forming a surface acoustic wave device, the method including: providing a piezoelectric layer having a first surface and a second surface opposite the first surface; and providing an interdigital transducer electrode in electrical communication with the piezoelectric layer, the interdigital transducer electrode including a bus bar and fingers extending from the bus bar, the fingers being at least partially positioned below the first surface and at least partially positioned over the first surface, and the bus bar being positioned over the first surface.

In some embodiments, the techniques described herein relate to a method wherein providing the interdigital transducer electrode includes forming a patterned recess in the piezoelectric layer such that the patterned recess is recessed relative to the first surface.

In some embodiments, the techniques described herein relate to a method wherein the patterned recess is at least partially formed in an active region of the surface acoustic wave device.

In some embodiments, the techniques described herein relate to a method wherein providing the interdigital transducer electrode further includes providing an interdigital transducer electrode material in the patterned recess.

In some embodiments, the techniques described herein relate to a method wherein the patterned recess is formed by way of etching and the interdigital transducer electrode material is provided by way of deposition.

In some aspects, the techniques described herein relate to a surface acoustic wave device including: a piezoelectric layer having a bus bar region having a first thickness and a finger region having a second thickness less than the first thickness; and an interdigital transducer electrode in electrical communication with the piezoelectric layer, the interdigital transducer electrode including a bus bar and fingers extending from the bus bar, the bus bar positioned in the bus bar region and the fingers positioned in the finger region.

In some embodiments, the techniques described herein relate to a surface acoustic wave device wherein the first thickness is at least 50 nanometers greater than the second thickness.

In some embodiments, the techniques described herein relate to a surface acoustic wave device wherein the finger region includes an active region and a gap region between the bus bar region and the active region, the piezoelectric layer has the second thickness in the active region.

In some embodiments, the techniques described herein relate to a surface acoustic wave device wherein the gap region has a third thickness equal to the second thickness.

In some embodiments, the techniques described herein relate to a surface acoustic wave device wherein the gap region has a third thickness greater than the second thickness.

In some embodiments, the techniques described herein relate to a surface acoustic wave device wherein the active region includes a center region and a border region between the center region and the gap region, the border region includes a piston mode structure.

In some embodiments, the techniques described herein relate to a surface acoustic wave device wherein the piston mode structure includes a trench formed in the piezoelectric layer.

In some embodiments, the techniques described herein relate to a surface acoustic wave device wherein the interdigital transducer electrode further includes a mini-bus bar in the gap region.

In some embodiments, the techniques described herein relate to a surface acoustic wave device further including a support substrate.

In some embodiments, the techniques described herein relate to a surface acoustic wave device further including an intermediate layer positioned between the support substrate and the piezoelectric layer.

In some aspects, the techniques described herein relate to a surface acoustic wave device including: a piezoelectric layer having a first surface and a second surface opposite the first surface; and an interdigital transducer electrode in electrical communication with the piezoelectric layer and positioned closer to the first surface than the second surface, the interdigital transducer electrode including a bus bar and fingers extending from the bus bar, a side of the bus bar facing the piezoelectric layer being positioned at a first height from the second surface, a side of the fingers in an active region facing the piezoelectric layer being positioned at a second height from the second surface, and the first height being greater than the second height.

In some embodiments, the techniques described herein relate to a surface acoustic wave device wherein the first height is at least 50 nanometers greater than the second height.

In some embodiments, the techniques described herein relate to a surface acoustic wave device wherein the finger region in a gap region between the bus bar region and the active region has a third height equal to or greater than the second height.

In some embodiments, the techniques described herein relate to a surface acoustic wave device wherein the interdigital transducer electrode further includes a mini-bus bar in the gap region.

In some embodiments, the techniques described herein relate to a surface acoustic wave device wherein the active region includes a center region and a border region between the center region and the gap region, the border region includes a piston mode structure.

In some embodiments, the techniques described herein relate to a surface acoustic wave device further including a support substrate and an intermediate layer positioned between the support substrate and the piezoelectric layer.

In some aspects, the techniques described herein relate to a method of forming a surface acoustic wave device, the method including: providing a piezoelectric layer having a bus bar region having a first thickness and a finger region having a second thickness less than the first thickness; and providing an interdigital transducer electrode including a bus bar and fingers extending from the bus bar, the bus bar positioned in the bus bar region and the fingers positioned in the finger region.

In some embodiments, the techniques described herein relate to a method wherein providing the interdigital transducer electrode includes forming a patterned recess in the piezoelectric layer so as to create a difference between the first thickness and the second thickness.

In some embodiments, the techniques described herein relate to a method wherein providing the interdigital transducer electrode further includes providing an interdigital transducer electrode material in the patterned recess. The method wherein the patterned recess is formed by way of etching and the interdigital transducer electrode material is provided by way of deposition.

### BRIEF DESCRIPTION OF THE DRAWINGS

Embodiments of this disclosure will now be described, by way of non-limiting example, with reference to the accompanying drawings.

FIG. 1A is a schematic cross-sectional side view of a surface acoustic wave (SAW) device according to an embodiment.

FIG. 1B is a schematic cross-sectional side view taken along another cross-section of the SAW device.

FIG. 1C is a schematic top plan view of the SAW device.

FIG. 1D is a schematic cross-sectional side view of a portion of the SAW device in a gap region.

FIG. 1E is a schematic cross-sectional side view of a portion of the SAW device in a center region.

FIG. 1F is a schematic cross-sectional side view of a portion of the SAW device in a border region.

FIGS. 2A to 2E show an example method of forming the SAW device.

FIG. 3A is a schematic perspective view with a wave propagation map of a portion of a SAW device that has an IDT electrode partially buried uniformly in the piezoelectric layer.

FIG. 3B is a schematic perspective view with a wave propagation map of a portion of the SAW device of FIGS. 1A-1F.

FIGS. 3C to 3E are graphs of simulation results showing performance of the SAW devices shown in FIGS. 3A and 3B.

FIG. 3F is an enlarged view of a portion of the graph of FIG. 3E.

FIG. 4A is a schematic top plan view of a portion of a SAW device shown as a location reference for FIGS. 4B to 4F.

FIGS. 4B to 4F are schematic cross-sectional side views of SAW devices with different transition locations between the buried region and non-buried region.

FIGS. 5A-5C are graphs of simulation results showing performance of the SAW devices of FIGS. 4B to 4F.

FIG. 5D is an enlarged view of a portion of the graph of FIG. 5C.

FIG. 6A is a schematic diagram of a transmit filter that includes a surface acoustic wave resonator according to an embodiment.

FIG. 6B is a schematic diagram of a receive filter that includes a surface acoustic wave resonator according to an embodiment.

FIG. 7 is a schematic diagram of a radio frequency module that includes a surface acoustic wave resonator according to an embodiment.

FIG. 8 is a schematic diagram of a radio frequency module that includes filters with surface acoustic wave resonators according to an embodiment.

FIG. 9 is a schematic block diagram of a module that includes an antenna switch and duplexers that include a surface acoustic wave resonator according to an embodiment.

FIG. 10A is a schematic block diagram of a module that includes a power amplifier, a radio frequency switch, and duplexers that include a surface acoustic wave resonator according to an embodiment.

FIG. 10B is a schematic block diagram of a module that includes filters, a radio frequency switch, and a low noise amplifier according to an embodiment.

FIG. 11A is a schematic block diagram of a wireless communication device that includes a filter with a surface acoustic wave resonator in accordance with one or more embodiments.

FIG. 11B is a schematic block diagram of another wireless communication device that includes a filter with a surface acoustic wave resonator in accordance with one or more embodiments.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices. Certain SAW devices may be referred to as SAW resonators. Any features of the SAW resonators discussed herein can be implemented in any suitable SAW device such as a multilayer piezoelectric substrate surface acoustic wave (MPS-SAW) device and a temperature compensated surface acoustic wave (TC-SAW) device.

In general, high quality factor (Q), large effective electromechanical coupling coefficient (k2), high frequency ability, and spurious free response can be significant aspects for acoustic wave elements to enable low-loss filters, delay lines, stable oscillators, and sensitive sensors. Also, a larger static capacitance can enable size reduction of a SAW device.

An MPS-SAW device can provide a relatively high quality factor (Q), a relatively large effective electromechanical coupling coefficient (k2), and a high-power durability. The MPS-SAW device can include a support substrate, a piezoelectric layer over the support substrate, and an interdigital transducer (IDT) electrode formed with the piezoelectric layer. The MPS-SAW devices are generally larger in size as compared to other types of SAW devices such as a TC-SAW device. A size reduction of the MPS-SAW device can be significant for the module floor plan, as well as for cost competitiveness.

To improve the effective electromechanical coupling coefficient (k2) and the static capacitance, an interdigital transducer (IDT) electrode can be embedded in a piezoelectric layer. A SAW device with such an embedded IDT electrode can provide a relatively high effective electromechanical coupling coefficient (k2) while reducing the size of the SAW device compared to a SAW device with the IDT electrode provided on the piezoelectric layer. However, in the SAW device with the embedded IDT electrode, the quality factor (Q) may degrade due to wave leakage to aperture direction, especially above its anti-resonant frequency. Therefore, it can be challenging to design a SAW device that can provide high quality factor (Q), large effective electromechanical coupling coefficient (k2), and high-power durability while reducing the size of the device.

Embodiments disclosed herein relate to SAW devices with an IDT electrode that is selectively positioned in a piezoelectric layer. A SAW device according to various embodiments can include a piezoelectric layer and an IDT electrode in electrical communication with the piezoelectric layer. The IDT electrode can include a first bus bar, first fingers that extend from the first bus bar, a second bus bar, and second fingers that extend from the second bus bar. The first and second fingers can be at least partially positioned in the piezoelectric layer below a surface of the piezoelectric layer. For example, the first and second fingers can be positioned in the piezoelectric layer at least in an active region of the SAW device. The first and second bus bars can be positioned on the surface of the piezoelectric layer. A combination of buried (e.g., partially or fully buried) fingers and less buried (e.g., non-buried) bus bars can mitigate or prevent wave leakage to aperture direction, thereby improving the quality factor (Q).

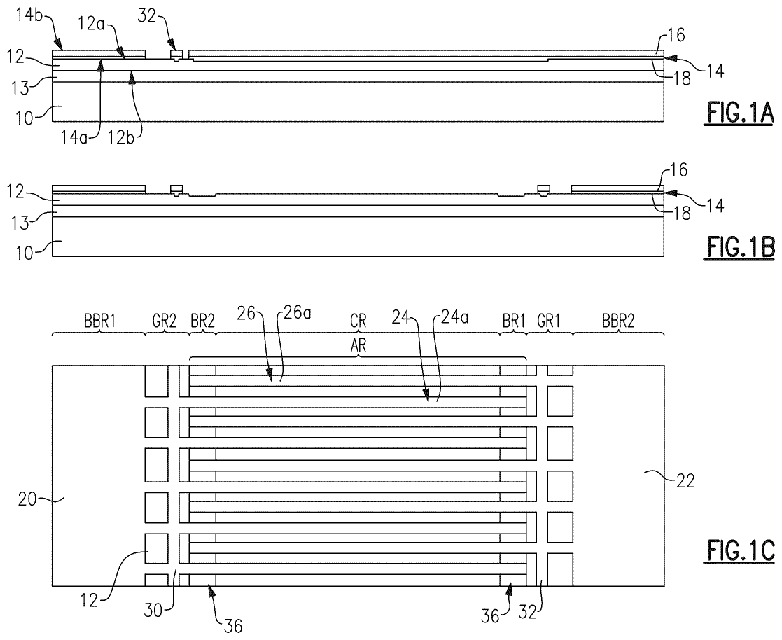

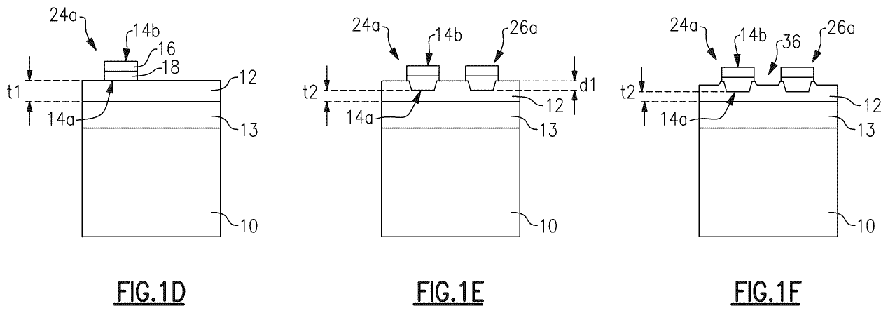

FIG. 1A is a schematic cross-sectional side view of a surface acoustic wave (SAW) device 1 according to an embodiment. FIG. 1B is a schematic cross-sectional side view taken along another cross-section of the SAW device 1. FIG. 1C is a schematic top plan view of the SAW device 1. FIG. 1D is a schematic cross-sectional side view of a portion of the SAW device 1 in a gap region. FIG. 1E is a schematic cross-sectional side view of a portion of the SAW device 1 in a center region. FIG. 1F is a schematic cross-sectional side view of a portion of the SAW 1 device in a border region.

The surface acoustic wave device 1 is an example of a multilayer piezoelectric substrate surface acoustic wave (MPS-SAW) device. The principles and advantages disclosed herein may be implemented in any SAW device, such as, a temperature compensated surface acoustic wave (TC-SAW) device. The SAW device 1 can include a support substrate 10, a piezoelectric layer 12, an intermediate layer 13 between the support substrate 10 and the piezoelectric layer 12, and an interdigital transducer (IDT) electrode 14 in electrical communication with the piezoelectric layer.

The support substrate 10 can be any suitable substrate layer, such as a silicon layer, a quartz layer, a ceramic layer, a glass layer, a spinel layer, a magnesium oxide spinel layer, a sapphire layer, a diamond layer, a silicon carbide layer, a silicon nitride layer, an aluminum nitride layer, or the like. The support substrate 10 can have a relatively high acoustic impedance. An acoustic impedance of the support substrate 10 can be higher than an acoustic impedance of the piezoelectric layer 12. For instance, the support substrate 10 can have a higher acoustic impedance than an acoustic impedance of lithium niobate and a higher acoustic impedance than lithium tantalate. The acoustic impedance of the support substrate 10 can be higher than an acoustic impedance of silicon dioxide (SiO₂). The SAW resonator 1 including the piezoelectric layer 12 on a support substrate 10 with relatively high thermal conductivity, such as silicon substrate, can achieve better thermal dissipation compared to a similar SAW resonator without the high impedance support substrate 10.

The piezoelectric layer 12 can include any suitable piezoelectric layer, such as a lithium based piezoelectric layer. In some embodiments, the piezoelectric layer 12 can be a lithium tantalate (LT) layer. For example, the piezoelectric layer 12 can be an LT layer having a cut angle of 20° (20° Y-cut X-propagation LT) or a cut angle of 60° (60° Y-cut X-propagation LT). For example, the piezoelectric layer 12 can be 20±10° Y-cut LT, 42±25° Y-cut LT, 42±20° Y-cut LT, 42±15° Y-cut LT, 42±10° Y-cut LT, 42±5° Y-cut LT, 60±20° Y-cut LT, 60±15° Y-cut LT, 60±10° Y-cut LT, or 60±5° Y-cut LT. Any other suitable piezoelectric material, such as a lithium niobate (LN) layer, can be used as the piezoelectric layer 12. For example, the piezoelectric layer 12 can be an LN layer having a cut angle of about 118° (118° Y-cut X-propagation LN) or more or a cut angle of about 132° (132Y-cut X-propagation LN) or less. For example, the piezoelectric layer 12 can be 125±20° Y-cut LN, 125±15° Y-cut LN, 125±10° Y-cut LN, or 125±5° Y-cut LN. A thickness of the piezoelectric layer 12 can be selected based on a wavelength λ or L of a surface acoustic wave generated by the SAW device 1 in certain applications. In some embodiments, the wavelength L can be in a range between, for example, 3 micrometers and 6 micrometers, 3.5 micrometers and 6 micrometers, 3 micrometers and 5.5 micrometers, or 3.5 micrometers and 5.5 micrometers. The piezoelectric layer 12 can be sufficiently thick to avoid significant frequency variation. For example, the thickness of the piezoelectric layer 12 can be in a range of 0.1L to 0.5, 0.1L to 0.3L, or 0.1L to 0.2L. Selecting the thickness of the piezoelectric layer 12 from these ranges can be critical in avoiding significant frequency variation and providing sufficient temperature coefficient of frequency for the SAW device 1. In some embodiments, the piezoelectric layer 12 can include lithium tantalate (LT) and lithium niobate (LN).

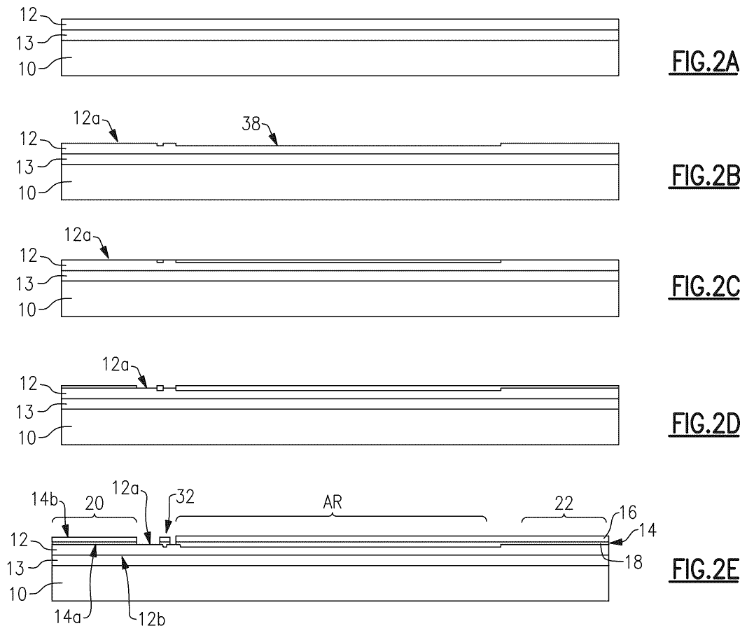

The piezoelectric layer 12 has a first surface 12a (e.g., an upper surface) and a second surface 12b (e.g., a lower surface) opposite the first surface 12a. The second surface 12b faces the intermediate layer 13. In some embodiments, the IDT electrode 14 can be at least partially positioned over the first surface 12a and at least partially positioned below the first surface 12a. A portion of the IDT electrode 14 below the first surface 12a can be positioned in a recess 38 (see FIG. 2B).

In some embodiments, the intermediate layer 13 can act as an adhesive layer. The intermediate layer 13 can include any suitable material. The intermediate layer 13 can be, for example, an oxide layer (e.g., a silicon dioxide (SiO₂) layer). One or more additional layers can be inserted between the intermediate layer 13 and the support substrate 10 to prevent or mitigate the unwanted electrical leakage on the surface of the support substrate 10. In some embodiments, one or more layers that include Poly-Si, Amorphas Si, Porous Si, SiN, and/or AlN can be disposed between the intermediate layer 13 and the support substrate 10.

The illustrated IDT electrode 14 can include a first layer 16 and a second layer 18. The IDT electrode 14 includes first bus bar 20, a second bus bar 22, a first set of fingers 24 that extends from the first bus bar 20, and a second set of fingers 26 that extends from the second bus bar 22. The first set of fingers 24 includes a first finger 24a and the second set of fingers 26 includes a second finger 26a. Each of the first set of fingers 24 and each of the second set of fingers 26 can be identical or generally similar to one another. In the SAW device 1, the IDT electrode 14 includes separate IDT layers (e.g., the first layer 16 and the second layer 18) that impact acoustic properties and electrical properties. Accordingly, in some embodiments, electrical properties, such as insertion loss, can be improved by adjusting one of the IDT layers without significantly impacting acoustic properties.

The first layer 16 of the IDT electrode 14 can be referred to as an upper electrode layer. The first layer 16 of the IDT electrode 14 is disposed over the second layer 18 of the IDT electrode 14. As illustrated, the first layer 16 of the IDT electrode 14 can have a first side in physical contact with the piezoelectric layer 12 and a second side in physical contact with the second layer 18 of the IDT electrode 14. The second layer 18 of the IDT electrode 14 can be referred to as a lower electrode layer. The second layer 18 of the IDT electrode 14 can be disposed between the first layer 16 of the IDT electrode 14 and the piezoelectric layer 12. As illustrated, the second layer 18 of the IDT electrode 14 can have a first side in physical contact with the first layer 16 of the IDT electrode 14. In some other embodiments, the first layer 16 and the second layer 18 can be switched.

The IDT electrode 14 can include any suitable material. For example, the first layer 16 can be tungsten (W) and the second layer 18 can be aluminum (Al) in certain embodiments. The IDT electrode 14 may include one or more other metals, such as copper (Cu), Magnesium (Mg), titanium (Ti), molybdenum (Mo), etc. The IDT electrode 14 may include alloys, such as AlMgCu, AlCu, etc. In some embodiments, a thickness of the first layer 16 can be in a range from 0.01L to 0.075L and a thickness of the second layer 18 can be in a range from 0.05L to 0.2L. For example, when the wavelength Lis 4 μm, the thickness of the first layer 16 can be about 40 nm to 300 nm and the thickness of the second layer 18 can be about 200 nm to 800 nm. Although the IDT electrode 14 has a dual-layer structure in the illustrated embodiments, any suitable principles and advantages disclosed herein can be applied to single layer IDT electrodes or multi-layer IDT electrodes that include three or more IDT layers. The IDT electrode 14 can be formed with (e.g., formed on or at least partially in) the piezoelectric layer 12. The piezoelectric layer 12 and the IDT electrode 14 can be provided in any suitable manner. For example, the piezoelectric layer 12 and the IDT electrode 14 can be provided in sequence. When the interdigital transducer electrode is provided at least partially in the piezoelectric layer 12, the piezoelectric layer 12 can be partially etched and/or provided in a plurality of steps.

The IDT electrode 14 has a first side 14a facing the piezoelectric layer 12 and a second side 14b opposite the first side 14a. In the illustrated embodiment, the first side 14a can be defined by a portion of the second layer 18 and the second side 14b can be defined by a portion of the first layer 16.

The SAW device 1 can include a first gap region GR1 between the first set of fingers 24 and the second bus bar 22, a second gap region GR2 between the second set of fingers 26 and the first bus bar 20, and an active region AR between the first and second gap regions GR1, GR2. In some embodiments, the IDT electrode 14 can include a first mini-bus bar 30 in the second gap region GR2 and a second mini-bus bar 32 in the first gap region GR1. The active region AR includes a center region CR, a first border region BR1 between the center region CR and the first gap region GR1, and a second border region BR2 between the center region CR and the second gap region GR2. The first bus bar 20 is positioned in a first bus bar region BBR1 and the second bus bar 22 is positioned in a second bas bar region BBR2. The first and second border regions BR1, BR2 can be regions within 0.5L, 1L, or 1.5L of the first and second sets of fingers 24, 26 from respective edges of the first and second sets of fingers 24, 26 or from the respective first or second gap regions GR1, GR2.

The piezoelectric layer 12 can include trenches 36 in the first border region BR1 and the second border region BR2. The trenches 36 can suppress the transverse mode, and function as a piston mode. In addition to or alternative to the trenches 36, any other suitable piston mode structure can be implemented with the SAW device 1. A hammer head structure, a mass loading strip, or a trench in a passivation layer are some examples of the piston mode structure.

In the SAW device 1, the first and second sets of fingers 24, 26 of the IDT electrode 14 are at least partially positioned below the first surface 12a and at least partially positioned over the first surface 12a in the active region AR, and the bus bars 20, 22 in the first and second bus bar regions BBR1, BBR2, and the first and second sets of fingers 24, 26 in the first and second gap regions GR1, GR2 are positioned on the first surface 12a. However, in some embodiments, a portion of the bus bars 20, 22 may be positioned below the first surface 12a. In such embodiments, a depth d1 from the first surface 12a of the piezoelectric layer 12 to the first side 14a of the IDT electrode 14 in the active region AR is greater than a depth from the first surface 12a to the first side 14a in the first and second bus bar regions BBR1, BBR2. In some embodiments, the first and second sets of fingers 24, 26 of the IDT electrode 14 can be at least partially positioned below the first surface 12a and at least partially positioned over the first surface 12a in the active region AR, and/or the first and second gap regions GR1, GR2.

In some embodiments, the depth d1 from the first surface 12a of the piezoelectric layer 12 to the first side 14a of the IDT electrode 14 in the active region AR can be in a range between 50 nanometers (nm) and 500 nm, 100 nm and 400 nm, 100 nm and 200 nm, or 50 nm and 200 nm. In some embodiments, a difference between the depth d1 in the active region AR and the depth from the first surface 12a to the first side 14a in the first and second bus bar regions BBR1, BBR2 can be greater than 50 nm. For example, the difference can be in a range between 50 nm and 500 nm, 50 nm and 300 nm, or 100 nm and 200 nm.

The piezoelectric layer 12 in the first and second bus bar regions BBR1, BBR2 has a first thickness t1 and the piezoelectric layer 12 in the active region AR has a second thickness t2. The first thickness t1 is greater than the second thickness t2. A side of the bus bar (e.g., the first side 14a of the IDT electrode 14 in the first and second bus bar regions BBR1, BBR2) facing the piezoelectric layer 12 can be positioned at a first height h1 from the second surface 12b, and a side of the first and second sets of fingers 24, 26 (e.g., the first side 14a of the IDT electrode 14) in an active region AR facing the piezoelectric layer 12 being positioned at a second height h2 from the second surface 12b. The first height h1 is greater than the second height h2. The first height h1 can be defined by the first thickness t1 of the piezoelectric layer 12 and the second height h2 can be defined by the second thickness t2 of the piezoelectric layer 12.

The SAW device 1 can include a buried region in which at least a portion of the IDT electrode 14 is buried or positioned below the first surface 12a of the piezoelectric layer 12 and a non-buried region in which no portion of the IDT electrode 14 is buried or positioned below the first surface 12a of the piezoelectric layer 12. In some embodiments, there can be a less-buried region in which the depth of the buried portion of the IDT electrode 14 is less than the buried region. The buried region can include the active region AR, and the non-buried region or the less-buried region can include the first and second bus bar regions BBR1, BBR2. The first and second gap regions GR1, GR2 can belong to the buried region, the non-buried region, or the less-buried region. For example, portions of the IDT electrode 14 in the first and second gap regions GR1, GR2 that are closer to the active region AR may belong to the buried region and portions of the IDT electrode 14 in the first and second gap regions GR1, GR2 that are closer to the first and second bus bar regions BBR1, BBR2 may belong to the non-buried region, or the less-buried region.

The SAW device 1 can be manufactured in any suitable manner. A method of forming the SAW device 1 can include providing a multi-layer piezoelectric substrate (MPS) including the support substrate 10, the piezoelectric layer 12, and the intermediate layer 13, and forming the IDT electrode 14. Forming the IDT electrode 14 can include removing (e.g., etching) at least a portion of the piezoelectric layer 12, providing (e.g., depositing) an IDT electrode material in the removed portion of the piezoelectric layer 12, polishing (e.g., chemical mechanical polishing (CMP)) the first surface 12a of the piezoelectric layer and a surface of the IDT material provided in the removed portion of the piezoelectric layer 12, providing additional IDT electrode material over the first surface 12a of the piezoelectric layer. Providing additional IDT electrode material over the first surface 12a of the piezoelectric layer may include providing more than one IDT materials in sequence. The method of forming the SAW device 1 can also include forming the trench 36 in the border region BR1, BR2.

FIGS. 2A to 2E show an example method of forming the IDT electrode 14. The method can include providing an MPS including the support substrate 10, the piezoelectric layer 12, and the intermediate layer 13 as shown in FIG. 2A. the method can include forming the IDT electrode 14. In FIG. 2B, at least a portion of the piezoelectric layer 12 can be removed to a form patterned recess 38. The portion of the piezoelectric layer 12 can be removed by way of, for example, etching. The patterned recess 38 can have a depth in a range between 50 nm and 500 nm, 50 nm and 300 nm, or 100 nm and 200 nm, in some embodiments. The patterned recess 38 can correspond to the buried region, and be equal to the depth d1 from the first surface 12a of the piezoelectric layer 12 to the first side 14a of the IDT electrode 14.

In FIG. 2C, an IDT electrode material can be provided. The IDT electrode material can be provided by way of, for example, deposition. The IDT electrode material can be provided at least in the patterned recess 38. In some embodiments, the IDT electrode material can be provided over the first surface 12a of the piezoelectric layer 12 and the IDT electrode material over the first surface 12a can be removed, for example, in a polishing process, such as a chemical mechanical polishing (CMP) process.

In FIGS. 2D and 2E, one or more additional IDT electrode materials can be provided. The one or more additional IDT electrode materials can be provided by way of, for example, deposition. In the example method shown in FIGS. 2A-2E, because the IDT electrode 14 in the active region AR has a portion that is positioned in the patterned recess 38 below the first surface 12a of the piezoelectric layer 12, a thickness of the IDT electrode 14 in the active region AR can be thicker than a thickness of the bus bars 20, 22.

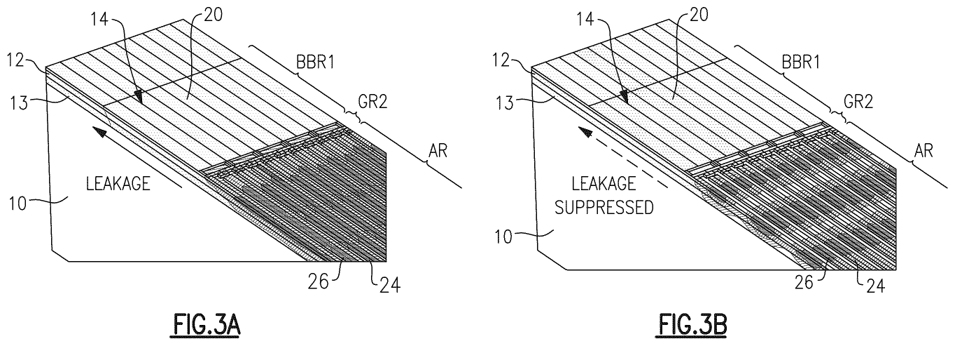

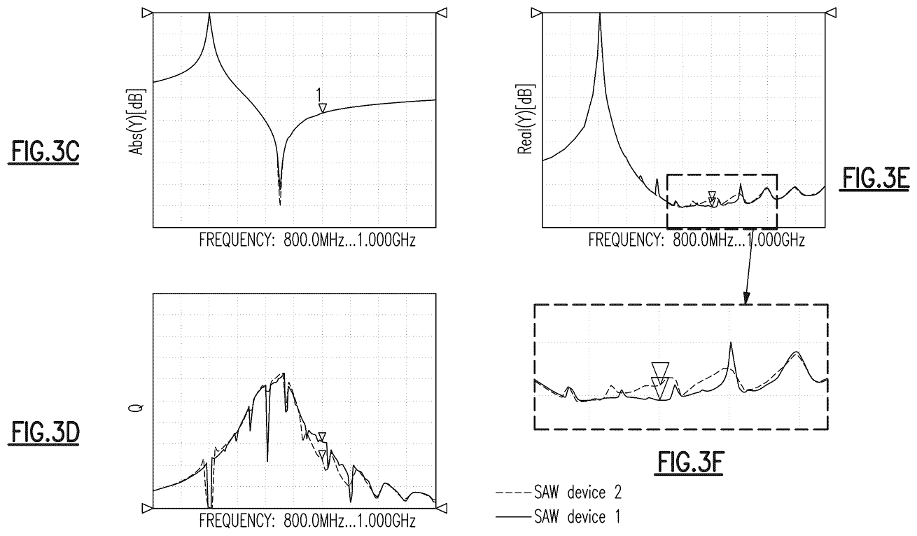

FIG. 3A is a schematic perspective view with a wave propagation map of a portion of a SAW device 2 that has an IDT electrode 14 partially buried uniformly in the piezoelectric layer 12. FIG. 3B is a schematic perspective view with a wave propagation map of a portion of the SAW device 1. In the SAW device 2, the IDT electrode is partially buried in all regions including the bus bar regions BBR1, BBR2, the gap regions GR1, GR2, and the active region AR. FIGS. 3C to 3E are graphs of simulation results showing performance of the SAW device 1 and the SAW device 2. FIG. 3F is an enlarged view of a portion of the graph of FIG. 3E.

FIGS. 3A to 3F indicate that when the IDT electrode 14 is buried in all regions, the wave generated in the active region AR may leak to aperture direction towards the bus bar 20 from the active region AR and causes degradation in the device performance. However, such leakage can be suppressed or prevented in the SAW device 1, and the degradation in device performance is mitigated.

A location of the transition between the buried region and non-buried or less-buried region can affect the performance of the SAW device. In some embodiments, the transition between the buried region and non-buried or less-buried region can be located in the first and second gap regions GR1, GR2.

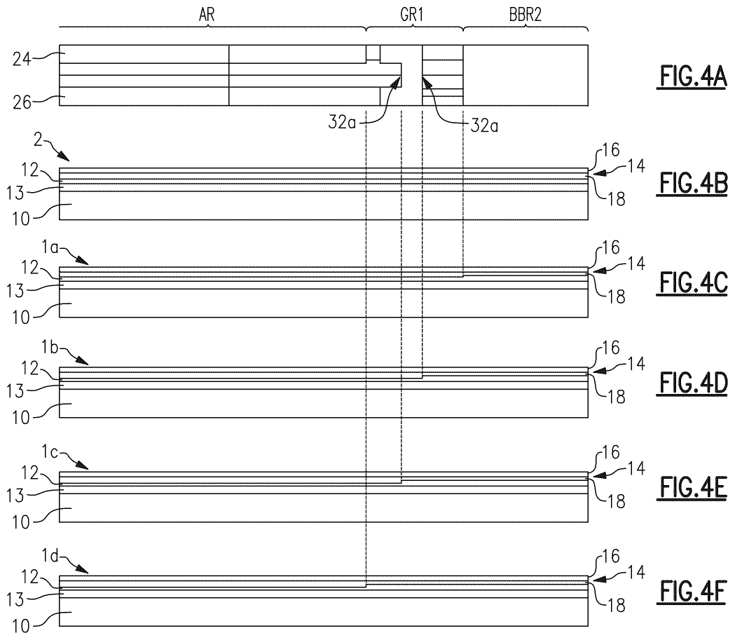

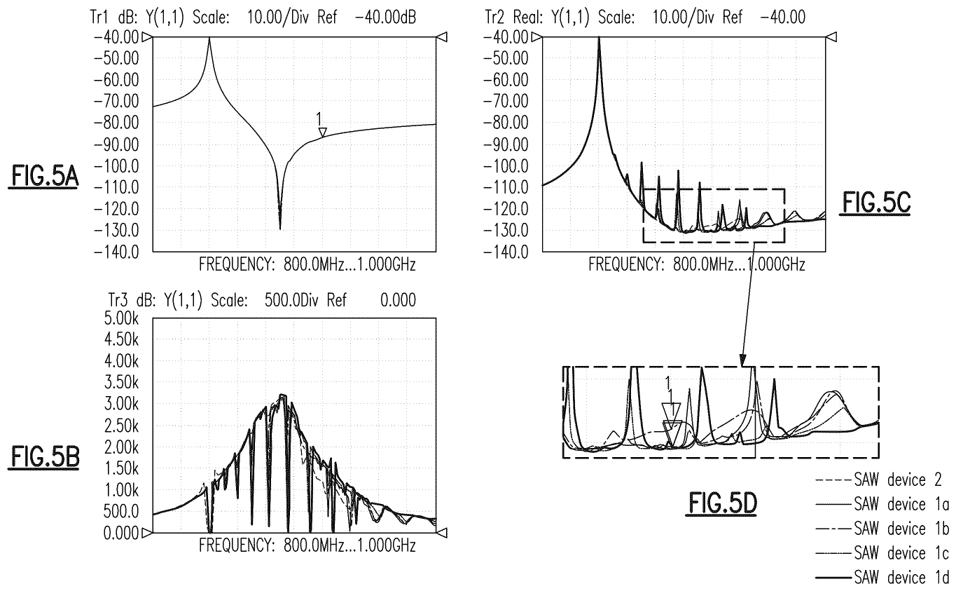

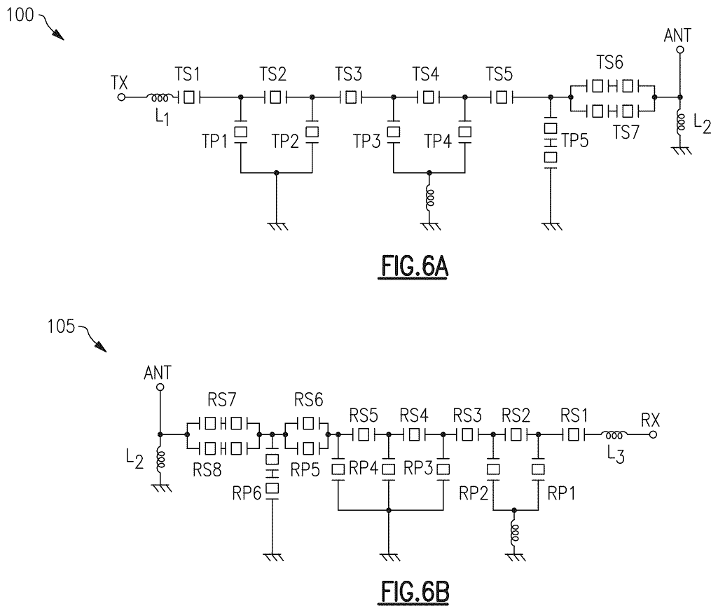

FIG. 4A is a schematic top plan view of a portion of a SAW device shown as a location reference for FIGS. 4B-4F. FIG. 4B is a schematic cross-sectional side view of the SAW device 2 of FIG. 3A. FIG. 4C is a schematic cross-sectional side view of a SAW device 1a according to an embodiment that includes an IDT electrode 14 including a bus bar 20 on the piezoelectric layer 12 and fingers 24, 26 partially positioned below a first surface 12a of the piezoelectric layer 12. FIG. 4D is a schematic cross-sectional side view of a SAW device 1b according to an embodiment that includes an IDT electrode 14 that has the transition between the buried region and non-buried or less-buried region located at an outer edge 32a of the mini-bus bar 32. FIG. 4E is a schematic cross-sectional side view of a SAW device 1c according to an embodiment that includes an IDT electrode 14 that has the transition between the buried region and non-buried or less-buried region located at an inner edge 32b of the mini-bus bar 32. FIG. 4E is a schematic cross-sectional side view of a SAW device 1d according to an embodiment that includes an IDT electrode 14 that has the transition between the buried region and non-buried or less-buried region located between the active region AR and the gap region GR1. The dashed lines between FIGS. 4A, 4B, 4C, 4D, 4E, and 4F indicate relative locations. FIGS. 5A-5C are graphs of simulation results showing performance of the SAW devices 2, 1a, 1b, 1c, and 1d. FIG. 5D is an enlarged view of a portion of the graph of FIG. 5C.

FIGS. 5A-5D indicate that the SAW devices 1a, 1b, 1c, and 1d provide a better wave trapping ability as compared to the SAW device 2. Also, the SAW devices 1b and 1c provide a better wave trapping ability as compared to the SAW devices 1a and 1d.

Various embodiments disclosed herein can be particularly beneficial when implemented in an MPS-SAW device. However, any suitable principles and advantages disclosed herein can also be beneficial when implemented in other types of SAW devices, such as a TC-SAW device.

An acoustic wave device (e.g., a SAW device) including any suitable combination of features disclosed herein can be included in a filter arranged to filter a radio frequency signal in a fifth generation (5G) New Radio (NR) operating band within Frequency Range 1 (FR1). A filter arranged to filter a radio frequency signal in a 5G NR operating band can include one or more conductive structures disclosed herein. FR1 can be from 410 MHz to 7.125 GHz, for example, as specified in a current 5G NR specification. One or more acoustic wave devices in accordance with any suitable principles and advantages disclosed herein can be included in a filter arranged to filter a radio frequency signal in a 4G LTE operating band and/or in a filter having a passband that includes a 4G LTE operating band and a 5G NR operating band.

FIG. 6A is a schematic diagram of an example transmit filter 100 that includes surface acoustic wave devices according to an embodiment. The transmit filter 100 can be a band pass filter. The illustrated transmit filter 100 is arranged to filter a radio frequency signal received at a transmit port TX and provide a filtered output signal to an antenna port ANT. Some or all of the SAW resonators TS1 to TS7 and/or TP1 to TP5 can be SAW devices in accordance with any suitable principles and advantages disclosed herein. For instance, one or more of the SAW resonators of the transmit filter 100 can be coupled by way of a conductive structure disclosed herein. Any suitable number of series SAW resonators and shunt SAW resonators can be included in a transmit filter 100.

FIG. 6B is a schematic diagram of a receive filter 105 that includes surface acoustic wave devices according to an embodiment. The receive filter 105 can be a band pass filter. The illustrated receive filter 105 is arranged to filter a radio frequency signal received at an antenna port ANT and provide a filtered output signal to a receive port RX. Some or all of the SAW resonators RS1 to RS8 and/or RP1 to RP6 can be SAW resonators in accordance with any suitable principles and advantages disclosed herein. Any suitable number of series SAW resonators and shunt SAW resonators can be included in a receive filter 105.

Although FIGS. 6A and 6B illustrate example ladder filter topologies, any suitable filter topology can include a conductive structure in accordance with any suitable principles and advantages disclosed herein. Example filter topologies include ladder topology, a lattice topology, a hybrid ladder and lattice topology, a multi-mode SAW filter, a multi-mode SAW filter combined with one or more other SAW resonators, and the like.

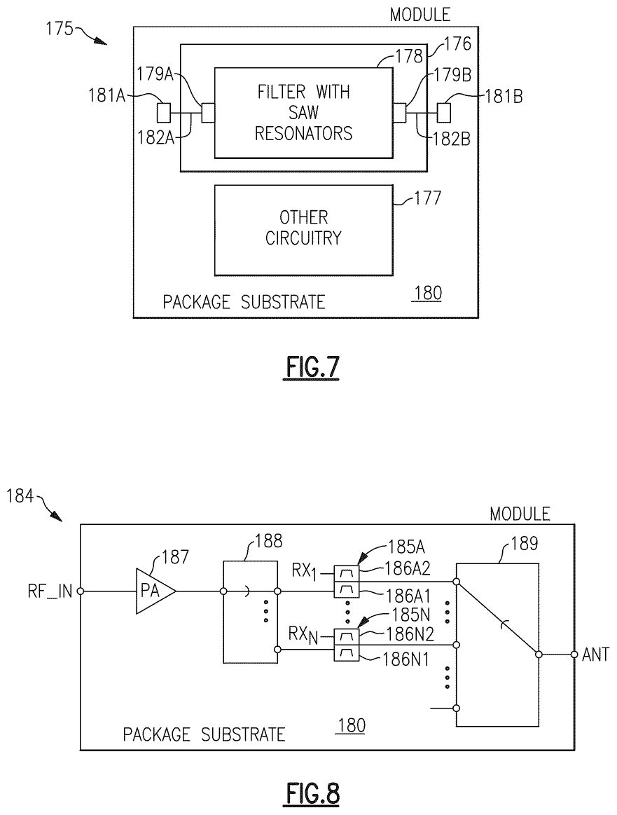

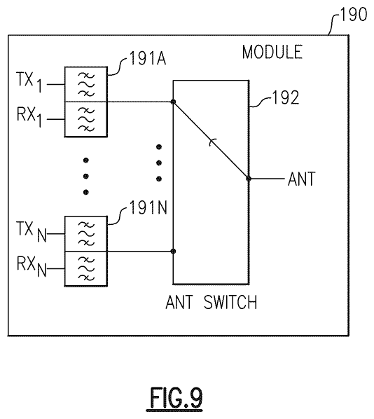

FIG. 7 is a schematic diagram of a radio frequency module 175 that includes a surface acoustic wave component 176. The illustrated radio frequency module 175 includes the SAW component 176 and other circuitry 177. The SAW component 176 can include one or more SAW resonators with any suitable combination of features of the SAW resonators disclosed herein. The SAW component 176 can include a SAW die that includes SAW resonators.

The SAW component 176 shown in FIG. 7 includes a filter 178 and terminals 179A and 179B. The filter 178 includes SAW resonators. One or more of the SAW resonators can be implemented in accordance with any suitable principles and advantages of any surface acoustic wave device disclosed herein. The terminals 179A and 178B can serve, for example, as an input contact and an output contact. The SAW component 176 and the other circuitry 177 are on a common packaging substrate 180 in FIG. 7. The package substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 180. The overmold structure can encapsulate some or all of the components of the radio frequency module 175.

FIG. 8 is a schematic diagram of a radio frequency module 184 that includes a surface acoustic wave resonator according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more SAW resonators in accordance with any suitable principles and advantages disclosed herein. Similarly, one or more of the receive filters 186A2 to 186N2 can include one or more SAW resonators in accordance with any suitable principles and advantages disclosed herein. Although FIG. 8 illustrates duplexers, any suitable principles and advantages disclosed herein can be implemented in other multiplexers (e.g., quadplexers, hexaplexers, octoplexers, etc.) and/or in switch-plexers and/or to standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

FIG. 9 is a schematic block diagram of a module 190 that includes duplexers 191A to 191N and an antenna switch 192. One or more filters of the duplexers 191A to 191N can include any suitable number of surface acoustic wave resonators in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190.

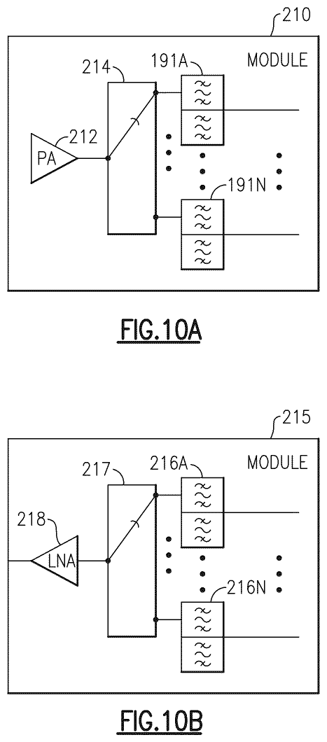

FIG. 10A is a schematic block diagram of a module 210 that includes a power amplifier 212, a radio frequency switch 214, and duplexers 191A to 191N in accordance with one or more embodiments. The power amplifier 212 can amplify a radio frequency signal. The radio frequency switch 214 can be a multi-throw radio frequency switch. The radio frequency switch 214 can electrically couple an output of the power amplifier 212 to a selected transmit filter of the duplexers 191A to 191N. One or more filters of the duplexers 191A to 191N can include any suitable number of surface acoustic wave resonators in accordance with any suitable principles and advantages discussed herein. Any suitable number of duplexers 191A to 191N can be implemented.

FIG. 10B is a schematic block diagram of a module 215 that includes filters 216A to 216N, a radio frequency switch 217, and a low noise amplifier 218 according to an embodiment. One or more filters of the filters 216A to 216N can include any suitable number of acoustic wave resonators in accordance with any suitable principles and advantages disclosed herein. Any suitable number of filters 216A to 216N can be implemented. The illustrated filters 216A to 216N are receive filters. In some embodiments, one or more of the filters 216A to 216N can be included in a multiplexer that also includes a transmit filter. The radio frequency switch 217 can be a multi-throw radio frequency switch. The radio frequency switch 217 can electrically couple an output of a selected filter of filters 216A to 216N to the low noise amplifier 218. In some embodiments, a plurality of low noise amplifiers can be implemented. The module 215 can include diversity receive features in certain applications.

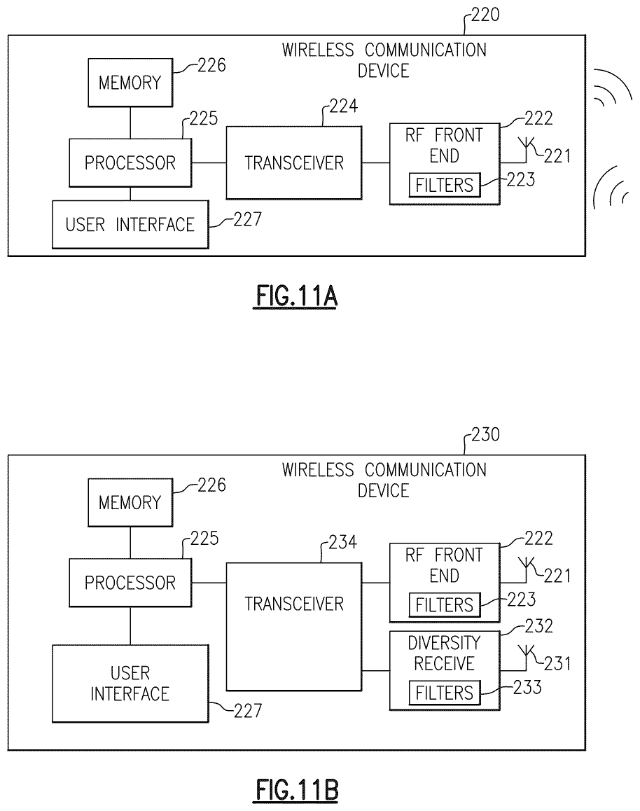

FIG. 11A is a schematic diagram of a wireless communication device 220 that includes filters 223 in a radio frequency front end 222 according to an embodiment. The filters 223 can include one or more SAW resonators in accordance with any suitable principles and advantages discussed herein. The wireless communication device 220 can be any suitable wireless communication device. For instance, a wireless communication device 220 can be a mobile phone, such as a smart phone. As illustrated, the wireless communication device 220 includes an antenna 221, an RF front end 222, a transceiver 224, a processor 225, a memory 226, and a user interface 227. The antenna 221 can transmit/receive RF signals provided by the RF front end 222. Such RF signals can include carrier aggregation signals. Although not illustrated, the wireless communication device 220 can include a microphone and a speaker in certain applications.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards. The filters 223 can include SAW resonators of a SAW component that includes any suitable combination of features discussed with reference to any embodiments discussed above.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

FIG. 11B is a schematic diagram of a wireless communication device 230 that includes filters 223 in a radio frequency front end 222 and a second filter 233 in a diversity receive module 232. The wireless communication device 230 is like the wireless communication device 220 of FIG. 11A, except that the wireless communication device 230 also includes diversity receive features. As illustrated in FIG. 11B, the wireless communication device 230 includes a diversity antenna 231, a diversity module 232 configured to process signals received by the diversity antenna 231 and including filters 233, and a transceiver 234 in communication with both the radio frequency front end 222 and the diversity receive module 232. The filters 233 can include one or more SAW resonators that include any suitable combination of features discussed with reference to any embodiments discussed above.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHZ, such as in a frequency range from about 450 MHz to 8.5 GHZ. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A surface acoustic wave device comprising:
a piezoelectric layer having a bus bar region having a first thickness and a finger region having a second thickness less than the first thickness; and
an interdigital transducer electrode in electrical communication with the piezoelectric layer, the interdigital transducer electrode including a bus bar and fingers extending from the bus bar, the bus bar positioned in the bus bar region and the fingers positioned in the finger region.

2. The surface acoustic wave device of claim 1 wherein the first thickness is at least 50 nanometers greater than the second thickness.

3. The surface acoustic wave device of claim 1 wherein the finger region includes an active region and a gap region between the bus bar region and the active region, the piezoelectric layer has the second thickness in the active region.

4. The surface acoustic wave device of claim 3 wherein the gap region has a third thickness equal to the second thickness.

5. The surface acoustic wave device of claim 3 wherein the gap region has a third thickness greater than the second thickness.

6. The surface acoustic wave device of claim 3 wherein the active region includes a center region and a border region between the center region and the gap region, the border region includes a piston mode structure.

7. The surface acoustic wave device of claim 6 wherein the piston mode structure includes a trench formed in the piezoelectric layer.

8. The surface acoustic wave device of claim 3 wherein the interdigital transducer electrode further includes a mini-bus bar in the gap region.

9. The surface acoustic wave device of claim 1 further comprising a support substrate.

10. The surface acoustic wave device of claim 9 further comprising an intermediate layer positioned between the support substrate and the piezoelectric layer.

11. A surface acoustic wave device comprising:
a piezoelectric layer having a first surface and a second surface opposite the first surface; and
an interdigital transducer electrode in electrical communication with the piezoelectric layer and positioned closer to the first surface than the second surface, the interdigital transducer electrode including a bus bar and fingers extending from the bus bar, a side of the bus bar facing the piezoelectric layer being positioned at a first height from the second surface, a side of the fingers in an active region facing the piezoelectric layer being positioned at a second height from the second surface, and the first height being greater than the second height.

12. The surface acoustic wave device of claim 11 wherein the first height is at least 50 nanometers greater than the second height.

13. The surface acoustic wave device of claim 11 wherein a finger region in a gap region between a bus bar region and the active region has a third height equal to or greater than the second height.

14. The surface acoustic wave device of claim 13 wherein the interdigital transducer electrode further includes a mini-bus bar in the gap region.

15. The surface acoustic wave device of claim 13 wherein the active region includes a center region and a border region between the center region and the gap region, the border region includes a piston mode structure.

16. The surface acoustic wave device of claim 11 further comprising a support substrate and an intermediate layer positioned between the support substrate and the piezoelectric layer.

17. A method of forming a surface acoustic wave device, the method comprising:
providing a piezoelectric layer having a bus bar region having a first thickness and a finger region having a second thickness less than the first thickness; and
providing an interdigital transducer electrode including a bus bar and fingers extending from the bus bar, the bus bar positioned in the bus bar region and the fingers positioned in the finger region.

18. The method of claim 17 wherein providing the interdigital transducer electrode includes forming a patterned recess in the piezoelectric layer so as to create a difference between the first thickness and the second thickness.

19. The method of claim 18 wherein providing the interdigital transducer electrode further includes providing an interdigital transducer electrode material in the patterned recess.

20. The method of claim 19 wherein the patterned recess is formed by way of etching and the interdigital transducer electrode material is provided by way of deposition.
